(19) United States
(12) Patent Application Publication
(10) Pub. No.: US 2024/0154003 A1
(43) Pub. Date: May 9, 2024

(54) SEMICONDUCTOR DEVICE

(71) Applicant: FUJI ELECTRIC CO., LTD., Kanagawa (JP)

(72) Inventors: Yosuke SAKURAI, Azumino-city (JP); Tatsuya NAITO, Matsumoto-city (JP); Seiji NOGUCHI, Matsumoto-city (JP); Motoyoshi KUBOUCHI, Matsumoto-city (JP); Naoko KODAMA, Matsumoto-city (JP); Hiroshi TAKISHITA, Matsumoto-city (JP)

(21) Appl. No.: 18/492,787

(22) Filed: Oct. 24, 2023

(30) Foreign Application Priority Data
Nov. 4, 2022 (JP) 2022-177696

(51) Int. Cl. H01L 29/32; H01L 27/06; H01L 29/739; H01L 29/861

(52) U.S. Cl. CPC H01L 29/32; H01L 27/0664; H01L 29/7397; H01L 29/8613

(57) ABSTRACT

Provided is a semiconductor device in which a boundary region between a transistor portion and a diode portion includes: a first portion which is in contact with the transistor portion and is not provided with a lifetime adjustment region; and a second portion which is in contact with the diode portion and to which the lifetime adjustment region of the diode portion extends, a density distribution of a lifetime killer in a first direction has a lateral slope where a density of the lifetime killer decreases from the second portion of the boundary region toward the first portion, a width of the first portion is smaller than a width of the second portion in the first direction, and the width of the first portion is equal to or larger than a width of the lateral slope in the first direction.

The contents of the following patent application(s) are incorporated herein by reference: NO. 2022-177696 filed in JP on Nov. 4, 2022

### BACKGROUND

### 1. Technical Field

The present invention relates to a semiconductor device.

### 2. Related Art

There is known a structure of a semiconductor device including a transistor portion and a diode portion, in which a defect region is partially formed in the diode portion to adjust a carrier lifetime (see, for example, Patent Documents 1 and 2).
Patent Document 1: WO2018/110703
Patent Document 2: WO2019/111572

### BRIEF DESCRIPTION OF THE DRAWINGS

FIG. 1 illustrates a top view showing an example of a semiconductor device 100 according to one embodiment of the present invention.

FIG. 2 illustrates an enlarged view of a region D in FIG. 1.

FIG. 3 illustrates a view showing an example of a cross section e-e in FIG. 2.

FIG. 4 shows an example of a lifetime killer density distribution 210 on a line a-a′ of FIG. 3.

FIG. 5 shows an example of a lifetime killer density distribution 220 on a line b-b′ of FIG. 3.

FIG. 6 illustrates a view showing another configuration example of a boundary region 200.

FIG. 7 illustrates a view showing another example of the cross section e-e.

FIG. 8 illustrates a view showing another example of the cross section e-e.

FIG. 9 illustrates a view showing another example of the cross section e-e.

FIG. 10 illustrates a view showing another example of the cross section e-e.

FIG. 11 illustrates a view showing another example of the cross section e-e.

FIG. 12 illustrates a view showing an exemplary arrangement of a first portion 201 and a second portion 202 in a top view.

FIG. 13 illustrates a view showing a relationship between an area ratio Sk/S and a reverse recovery loss Err of a diode portion 80.

FIG. 14 illustrates a view showing a relationship among a lifetime killer density, a carrier lifetime, and a charged particle concentration in a lifetime adjustment region 206.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solution of the invention.

As used herein, one side in a direction parallel to a depth direction of a semiconductor substrate is referred to as “upper” and the other side is referred to as “lower”. One surface of two principal surfaces of a substrate, a layer, or other member is referred to as an upper surface, and the other surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate a height direction with respect to the ground. Note that a +Z axis direction and a −Z axis direction are directions opposite to each other. When the Z axis direction is described without describing the signs, it means that the direction is parallel to the +Z axis and the −Z axis.

In the present specification, orthogonal axes parallel to an upper surface and lower surface of a semiconductor substrate are referred to as the X axis and the Y axis. Further, an axis perpendicular to the upper surface and the lower surface of the semiconductor substrate is referred to as the Z axis. In the present specification, the direction of the Z axis may be referred to as the depth direction. Further, in the present specification, a direction parallel to the upper surface and the lower surface of the semiconductor substrate may be referred to as a horizontal direction, including the X axis direction and the Y axis direction.

A region from a center of the semiconductor substrate in the depth direction to the upper surface of the semiconductor substrate may be referred to as an upper surface side. Similarly, the region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of a doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type, or a semiconductor presenting a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking polarities of charges into account. As an example, when the donor concentration is N_{D} and the acceptor concentration is N_{A}, the net doping concentration at any position is given as N_{D}-N_{A}. In the present specification, the net doping concentration may be simply referred to as the doping concentration.

The donor has a function of supplying electrons to a semiconductor. The acceptor has a function of receiving electrons from the semiconductor. The donor and acceptor are not limited to the impurities themselves. For example, a VOH defect which is a combination of a vacancy (V), oxygen (O), and hydrogen (H) existing in the semiconductor functions as the donor that supplies electrons. The hydrogen donor may be a donor obtained by the combination of at least a vacancy (V) and hydrogen (H). Alternatively, interstitial Si—H which is a combination of interstitial silicon (Si-i) and hydrogen in a silicon semiconductor also functions as the donor that supplies electrons. In the present specification, the VOH defect or interstitial Si—H may be referred to as a hydrogen donor.

In the present specification, bulk donors of the N type are distributed throughout the semiconductor substrate. The bulk donor is a dopant donor substantially uniformly contained in an ingot during the manufacture of the ingot from which the semiconductor substrate is made. The bulk donor of this example is an element other than hydrogen. The dopant of the bulk donor is, for example, phosphorus, antimony, arsenic, selenium, or sulfur, but the present invention is not limited to these. The bulk donor of this example is phosphorus. The bulk donor is also contained in the P type region. The semiconductor substrate may be a wafer cut out from a semiconductor ingot, or may be a chip obtained by singulating the wafer. The semiconductor ingot may be manufactured by any of a Chokralski method (CZ method), a magnetic field applied Chokralski method (MCZ method), or a float zone method (FZ method). The ingot of this example is manufactured by the MCZ method. An oxygen concentration contained in the substrate manufactured by the MCZ method is 1×10¹⁷ to 7×10¹⁷/cm³. The oxygen concentration contained in the substrate manufactured by the FZ method is 1×10¹⁵ to 5×10¹⁶/cm³. When the oxygen concentration is high, hydrogen donors tend to be easily generated. A chemical concentration of a bulk donor distributed throughout the semiconductor substrate may be used for the bulk donor concentration, which may also be a value from 90% to 100% of the chemical concentration. Further, as the semiconductor substrate, a non-doped substrate not containing a dopant such as phosphorus may be used. In that case, the bulk donor concentration (DO) of the non-doped substrate is, for example, 1×10¹⁰/cm³ or more and 5×10¹²/cm³ or less. The bulk donor concentration (DO) of the non-doped substrate is preferably 1×10¹¹/cm³ or more. The bulk donor concentration (DO) of the non-doped substrate is preferably 5×10¹²/cm³ or less. Note that each concentration in the present invention may be a value at room temperature. As the value at room temperature, a value at 300 K (Kelvin) (about 26.9° C.) may be used as an example.

In the present specification, a description of a P+ type or an N+ type means a higher doping concentration than that of the P type or the N type, and a description of a P− type or an N− type means a lower doping concentration than that of the P type or the N type. Further, in the present specification, a description of a P++ type or an N++ type means a higher doping concentration than that of the P+ type or the N+ type. In the present specification, a unit system is the SI base unit system unless otherwise stated in particular. Although a unit of length may be expressed in cm, calculations may be carried out after conversion to meters (m).

A chemical concentration in the present specification indicates an atomic density of an impurity measured regardless of an electrical activation state. The chemical concentration can be measured by, for example, secondary ion mass spectrometry (SIMS). The net doping concentration described above can be measured by capacitance-voltage profiling (CV profiling). Furthermore, a carrier concentration measured by a spreading resistance profiling method (SRP method) may be set as the net doping concentration. The carrier concentration measured by the CV profiling or the SRP method may be set as a value in a thermal equilibrium state. Furthermore, in a region of an N type, the donor concentration is sufficiently higher than the acceptor concentration, and therefore, the carrier concentration in the region may be set as the donor concentration. Similarly, in a region of a P type, the carrier concentration in the region may be set as the acceptor concentration. In the present specification, the doping concentration of the N type region may be referred to as the donor concentration, and the doping concentration of the P type region may be referred to as the acceptor concentration.

When a concentration distribution of the donor, acceptor, or net doping has a peak in a region, a value of the peak may be set as the concentration of the donor, acceptor, or net doping in the region. In a case where the concentration of the donor, acceptor, or net doping is substantially uniform in a region, or the like, an average value of the concentration of the donor, acceptor, or net doping in the region may be set as the concentration of the donor, acceptor, or net doping. In the present specification, atoms/cm³ or/cm³ is used to indicate a concentration per unit volume. This unit is used for a concentration of a donor or an acceptor in a semiconductor substrate, or a chemical concentration. A notation of atoms may be omitted.

The carrier concentration measured by the SRP method may be lower than the concentration of the donor or the acceptor. In a range where a current flows when a spreading resistance is measured, the carrier mobility of the semiconductor substrate may be lower than a value in a crystalline state. The reduction in carrier mobility occurs when carriers are scattered due to disorder (disorder) of a crystal structure due to a lattice defect or the like.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorus or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen.

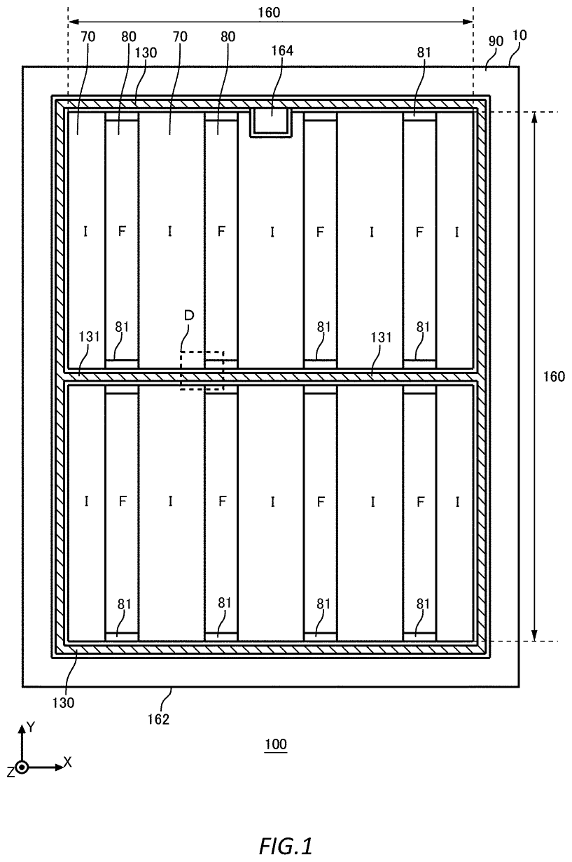

FIG. 1 illustrates a top view showing an example of a semiconductor device 100 according to one embodiment of the present invention. FIG. 1 shows a position at which each member is projected on an upper surface of a semiconductor substrate 10. FIG. 1 shows merely some members of the semiconductor device 100, and omits illustrations of some members.

The semiconductor device 100 includes the semiconductor substrate 10. The semiconductor substrate 10 is a substrate that is formed of a semiconductor material. As an example, the semiconductor substrate 10 is a silicon substrate. The semiconductor substrate 10 has an end side 162 in the top view. When merely referred to as the top view in the present specification, it means that the semiconductor substrate 10 is viewed from an upper surface side. The semiconductor substrate 10 of this example has two sets of end sides 162 opposite to each other in the top view. In FIG. 1, the X axis and the Y axis are parallel to any of the end sides 162. In addition, the Z axis is perpendicular to the upper surface of the semiconductor substrate 10.

The semiconductor substrate 10 is provided with an active portion 160. The active portion 160 is a region where a main current flows in the depth direction between the upper surface and a lower surface of the semiconductor substrate 10 when the semiconductor device 100 operates. An emitter electrode is provided above the active portion 160, but is omitted in FIG. 1. The active portion 160 may refer to a region that overlaps with the emitter electrode in the top view. Further, a region sandwiched by the active portion 160 in the top view may also be included in the active portion 160.

The active portion 160 is provided with a transistor portion 70 including a transistor element such as an insulated gate bipolar transistor (IGBT) and a diode portion 80 including a diode element such as a freewheeling diode (FWD). In the example of FIG. 1, the transistor portion 70 and the diode portion 80 are alternately arranged along a predetermined first direction (the X axis direction in this example) on the upper surface of the semiconductor substrate 10. The semiconductor device 100 of this example is a reverse-conducting IGBT (RC-IGBT). A boundary region is arranged between the transistor portion 70 and the diode portion 80 in the X axis direction, but is omitted in FIG. 1.

In FIG. 1, a region where each of the transistor portions 70 is arranged is indicated by a symbol “I”, and a region where each of the diode portions 80 is arranged is indicated by a symbol F. In the present specification, a direction different from the first direction in the top view may be referred to as a second direction (the Y axis direction in FIG. 1). The second direction may be a direction perpendicular to the first direction. Each of the transistor portion 70 and the diode portion 80 may have a longitudinal length in the second direction. In other words, a length of each of the transistor portions 70 in the Y axis direction is larger than the width in the X axis direction. Similarly, the length of each of the diode portions 80 in the Y axis direction is larger than the width in the X axis direction. The second direction of the transistor portion 70 and the diode portion 80, and the longitudinal direction of each trench portion described below may be the same.

Each of the diode portions 80 includes a cathode region of the N+ type in a region in contact with the lower surface of the semiconductor substrate 10. In the present specification, a region where the cathode region is provided is referred to as the diode portion 80. In other words, the diode portion 80 is a region that overlaps with the cathode region in the top view. On the lower surface of the semiconductor substrate 10, a collector region of the P+ type may be provided in a region other than the cathode region. In the present specification, the diode portion 80 may also include an extension region 81 where the diode portion 80 extends to a gate runner described below in the Y axis direction. The collector region is provided on a lower surface of the extension region 81.

The transistor portion 70 has the collector region of the P+ type in a region in contact with the lower surface of the semiconductor substrate 10. Further, in the transistor portion 70, an emitter region of the N type, a base region of the P type, and a gate structure having a gate conductive portion and a gate dielectric film are periodically arranged on the upper surface side of the semiconductor substrate 10.

The semiconductor device 100 may have one or more pads above the semiconductor substrate 10. The semiconductor device 100 of this example has a gate pad 164. The semiconductor device 100 may have a pad such as an anode pad, a cathode pad, and a current detection pad. Each pad is arranged in a region close to the end side 162. The region close to the end side 162 refers to a region between the end side 162 and the emitter electrode in the top view. When the semiconductor device 100 is mounted, each pad may be connected to an external circuit via a wiring such as a wire.

A gate potential is applied to the gate pad 164. The gate pad 164 is electrically connected to a conductive portion of a gate trench portion of the active portion 160. The semiconductor device 100 includes a gate runner that connects the gate pad 164 and the gate trench portion. In FIG. 1, the gate runner is hatched with diagonal lines.

The gate runner of this example includes an outer circumferential gate runner 130 and an active-side gate runner 131. The outer circumferential gate runner 130 is arranged between the active portion 160 and the end side 162 of the semiconductor substrate 10 in the top view. The outer circumferential gate runner 130 of this example encloses the active portion 160 in the top view. A region enclosed by the outer circumferential gate runner 130 in the top view may be the active portion 160. In addition, a well region is formed below the gate runner. The well region is a P type region having a higher concentration than the base region described below, and is formed to a position deeper than the base region from the upper surface of the semiconductor substrate 10. In the top view, the region enclosed by the well region may be the active portion 160.

The outer circumferential gate runner 130 is connected to the gate pad 164. The outer circumferential gate runner 130 is arranged above the semiconductor substrate 10. The outer circumferential gate runner 130 may be a metal wiring containing aluminum or the like.

The active-side gate runner 131 is provided in the active portion 160. Providing the active-side gate runner 131 in the active portion 160 can reduce a variation in wiring length from the gate pad 164 for each region of the semiconductor substrate 10.

The outer circumferential gate runner 130 and the active-side gate runner 131 are connected to the gate trench portion of the active portion 160. The outer circumferential gate runner 130 and the active-side gate runner 131 are arranged above the semiconductor substrate 10. The outer circumferential gate runner 130 and the active-side gate runner 131 may be a wiring formed of a semiconductor such as polysilicon doped with an impurity.

The active-side gate runner 131 may be connected to the outer circumferential gate runner 130. The active-side gate runner 131 of this example is provided extending in the X axis direction so as to cross the active portion 160 from one outer circumferential gate runner 130 to the other outer circumferential gate runner 130 sandwiching the active portion 160, substantially at the center of the Y axis direction. When the active portion 160 is divided by the active-side gate runner 131, the transistor portion 70 and the diode portion 80 may be alternately arranged in the X axis direction in each of the divided regions.

The semiconductor device 100 may include a temperature sensing portion (not shown) that is a PN junction diode formed of polysilicon or the like, and a current detection portion (not shown) that simulates an operation of the transistor portion provided in the active portion 160.

The semiconductor device 100 of this example includes an edge termination structure portion 90 between the active portion 160 and the end side 162 in the top view. The edge termination structure portion 90 of this example is arranged between the outer circumferential gate runner 130 and the end side 162. The edge termination structure portion 90 relaxes an electric field strength on the upper surface side of the semiconductor substrate 10. The edge termination structure portion 90 may include at least one of a guard ring, a field plate, or a RESURF annularly provided to enclose the active portion 160.

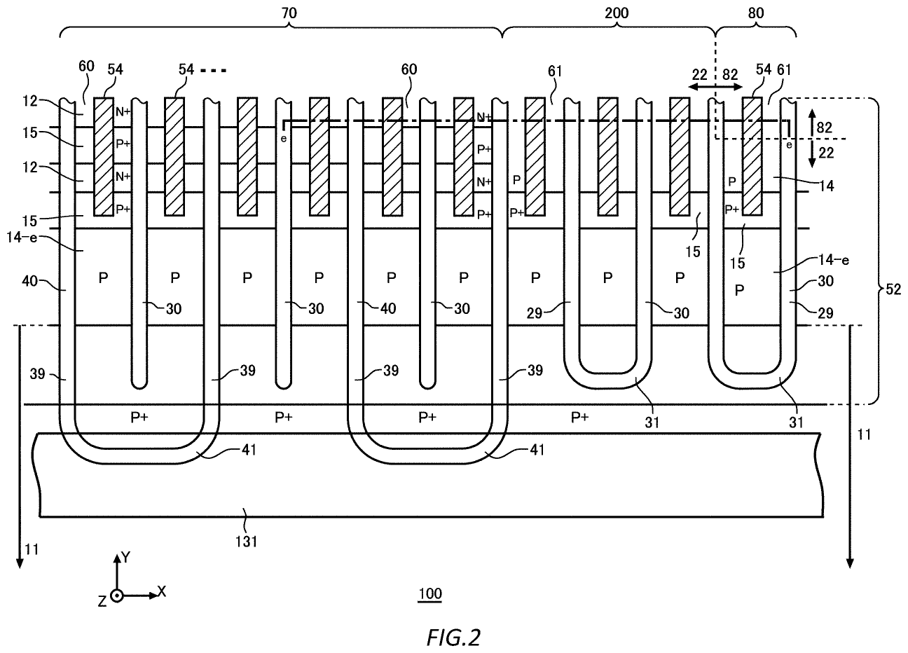

FIG. 2 illustrates an enlarged view of a region D in FIG. 1. The region D is a region including the transistor portion 70, the diode portion 80, and the active-side gate runner 131. Although omitted in FIG. 1, a boundary region 200 is arranged between the transistor portion 70 and the diode portion 80 in the X axis direction. The semiconductor device 100 of this example includes a gate trench portion 40, a dummy trench portion 30, a well region 11, an emitter region 12, a base region 14, and a contact region 15, which are provided inside the semiconductor substrate 10 on the upper surface side. The gate trench portion 40 and the dummy trench portion 30 each are an example of the trench portion. In addition, the semiconductor device 100 of this example includes an emitter electrode 52 and the active-side gate runner 131 which are provided above the upper surface of the semiconductor substrate 10. The emitter electrode 52 is an example of an upper surface electrode. The emitter electrode 52 and the active-side gate runner 131 are provided separate from each other.

An interlayer dielectric film is provided between the emitter electrode 52 and the active-side gate runner 131, and the upper surface of the semiconductor substrate 10, but the interlayer dielectric film is omitted in FIG. 2. In the interlayer dielectric film of this example, a contact hole 54 is provided passing through the interlayer dielectric film. In FIG. 2, each contact hole 54 is hatched with the diagonal lines.

The emitter electrode 52 is provided above the gate trench portion 40, the dummy trench portion 30, the well region 11, the emitter region 12, the base region 14, and the contact region 15. The emitter electrode 52 is in contact with the emitter region 12, the contact region 15, and the base region 14 on the upper surface of the semiconductor substrate 10, through the contact hole 54. Further, the emitter electrode 52 is connected to a dummy conductive portion in the dummy trench portion 30 through the contact hole provided in the interlayer dielectric film. The emitter electrode 52 may be connected to the dummy conductive portion of the dummy trench portion 30 at an edge of the dummy trench portion 30 in the Y axis direction. The dummy conductive portion of the dummy trench portion 30 does not need to be connected to the emitter electrode 52 and the gate conductive portion, and may be controlled to be set at a potential different from the potential of the emitter electrode 52 and the potential of the gate conductive portion.

The active-side gate runner 131 is connected to the gate trench portion 40 through the contact hole provided in the interlayer dielectric film. The active-side gate runner 131 may be connected to a gate conductive portion of the gate trench portion 40 in an edge portion 41 of the gate trench portion 40 in the Y axis direction. The active-side gate runner 131 is not connected to the dummy conductive portion in the dummy trench portion 30.

The emitter electrode 52 is formed of a material including metal. FIG. 2 shows a range where the emitter electrode 52 is provided. For example, at least a part of a region of the emitter electrode 52 is formed of aluminum or an aluminum-silicon alloy, for example, a metal alloy such as AlSi and AlSiCu. The emitter electrode 52 may have a barrier metal formed of titanium, a titanium compound, or the like below a region formed of aluminum or the like. Further, a plug, which is formed by embedding tungsten or the like so as to be in contact with the barrier metal and aluminum or the like, may be included in the contact hole.

The well region 11 is provided so as to overlap with the active-side gate runner 131. The well region 11 is provided so as to extend with a predetermined width also in a range not overlapping with the active-side gate runner 131. The well region 11 of this example is provided away from an end of the contact hole 54 in the Y axis direction toward the active-side gate runner 131 side. The well region 11 is a region of a second conductivity type in which the doping concentration is higher than the base region 14. The base region 14 of this example is a P type, and the well region 11 is a P+ type.

Each of the transistor portion 70, the diode portion 80, and the boundary region 200 includes a plurality of trench portions arranged in the first direction. In the transistor portion 70 of this example, one or more gate trench portions 40 and one or more dummy trench portions 30 are alternately provided along the first direction. In the diode portion 80 of this example, the plurality of dummy trench portions 30 are provided along the first direction. In the diode portion 80 of this example, the gate trench portion 40 is not provided. In the boundary region 200 of this example, the plurality of dummy trench portions 30 are provided along the first direction. In the boundary region 200 of this example, the gate trench portion 40 is not provided.

The gate trench portion 40 of this example may have two linear portions 39 extending along the second direction perpendicular to the first direction (portions of a trench that are linear along the second direction), and the edge portion 41 connecting the two linear portions 39. The second direction in FIG. 2 is the Y axis direction.

At least a part of the edge portion 41 is preferably provided in a curved shape in a top view. By connecting end portions of the two linear portions 39 in the Y axis direction by the edge portion 41, it is possible to relax an electric field strength at the end portions of the linear portions 39.

In the transistor portion 70, the dummy trench portions 30 are provided between the respective linear portions 39 of the gate trench portions 40. Between the respective linear portions 39, one dummy trench portion 30 may be provided, or a plurality of dummy trench portions 30 may be provided. The dummy trench portion 30 may have a linear shape extending in the second direction, or may have linear portions 29 and an edge portion 31 similar to the gate trench portion 40. The semiconductor device 100 shown in FIG. 2 includes both of the linear dummy trench portion 30 having no edge portion 31, and the dummy trench portion 30 having the edge portion 31.

A diffusion depth of the well region 11 may be deeper than the depth of the gate trench portion 40 and the dummy trench portion 30. The end portions of the gate trench portion 40 and the dummy trench portion 30 in the Y axis direction are provided in the well region 11 in a top view. In other words, the bottom of each trench portion in the depth direction is covered with the well region 11 at the end portion of each trench portion in the Y axis direction. With this configuration, the electric field strength at the bottom of each trench portion can be relaxed.

A mesa portion is provided between the respective trench portions in the first direction. The mesa portion refers to a region sandwiched between the trench portions inside the semiconductor substrate 10. As an example, an upper end of the mesa portion is the upper surface of the semiconductor substrate 10. The depth position of the lower end of the mesa portion is the same as the depth position of the lower end of the trench portion. The mesa portion of this example is provided extending in the second direction (the Y axis direction) along the trench, on the upper surface of the semiconductor substrate 10. In this example, a mesa portion 60 is provided in the transistor portion 70, and a mesa portion 61 is provided in the diode portion 80 and the boundary region 200. In the case of simply mentioning “mesa portion” in the present specification, the portion refers to each of the mesa portion 60 and the mesa portion 61.

Each mesa portion is provided with the base region 14. Of the base regions 14 exposed on the upper surface of the semiconductor substrate 10 in the mesa portion, a region arranged closest to the active-side gate runner 131 is assumed to be a base region 14-e. While FIG. 2 shows the base region 14-e arranged at one end portion of each mesa portion in the second direction, the base region 14-e is also arranged at the other end portion of each mesa portion. In each mesa portion, at least one of the emitter region 12 of the first conductivity type or the contact region 15 of the second conductivity type may be provided in a region sandwiched between the base regions 14-e in a top view. The emitter region 12 of this example is an N+ type, and the contact region 15 is a P+ type. The emitter region 12 and the contact region 15 may be provided between the base region 14 and the upper surface of the semiconductor substrate 10 in the depth direction.

The mesa portion 60 of the transistor portion 70 has the emitter region 12 exposed on the upper surface of the semiconductor substrate 10. The emitter region 12 is provided in contact with the gate trench portion 40. The mesa portion 60 in contact with the gate trench portion 40 may be provided with the contact region 15 exposed on the upper surface of the semiconductor substrate 10.

Each of the contact region 15 and the emitter region 12 in the mesa portion 60 is provided from one trench portion to the other trench portion in the X axis direction. As an example, the contact region 15 and the emitter region 12 of the mesa portion 60 are alternately arranged along the second direction of the trench portion (the Y axis direction).

In another example, the contact region 15 and the emitter region 12 of the mesa portion 60 may be provided in a stripe pattern along the second direction of the trench portion (the Y axis direction). For example, the emitter region 12 is provided in a region in contact with the trench portion, and the contact region 15 is provided in a region sandwiched between the emitter regions 12.

The mesa portion 61 of the diode portion 80 and the boundary region 200 is not provided with the emitter region 12. The base region 14 and the contact region 15 may be provided on an upper surface of the mesa portion 61. In the region sandwiched between the base regions 14-e on the upper surface of the mesa portion 61, the contact region 15 may be provided in contact with each base region 14-e. The base region 14 may be provided in a region sandwiched between the contact regions 15 on the upper surface of the mesa portion 61. The base region 14 may be arranged in the entire region sandwiched between the contact regions 15.

The contact hole 54 is provided above each mesa portion. The contact hole 54 is arranged in the region sandwiched between the base regions 14-e. The contact hole 54 of this example is provided above each region of the contact region 15, the base region 14, and the emitter region 12. The contact hole 54 is not provided in regions corresponding to the base region 14-e and the well region 11. The contact hole 54 may be arranged at the center of the mesa portion 60 in the first direction (the X axis direction).

In the diode portion 80, a cathode region 82 of the N+ type is provided in a region in direct contact with the lower surface of the semiconductor substrate 10. On the lower surface of the semiconductor substrate 10, a collector region 22 of the P+ type may be provided in a region where the cathode region 82 is not provided. The cathode region 82 and the collector region 22 are provided between the lower surface 23 of the semiconductor substrate 10 and a buffer region 20. In FIG. 2, a boundary between the cathode region 82 and the collector region 22 is indicated by a dotted line.

The cathode region 82 is arranged apart from the well region 11 in the Y axis direction. With this configuration, a distance between the P type region (the well region 11) which has a relatively high doping concentration and is formed up to a deep position and the cathode region 82 is ensured, so that the breakdown voltage can be improved. The end portion of the cathode region 82 of this example in the Y axis direction is arranged farther away from the well region 11 than the end portion of the contact hole 54 in the Y axis direction. In another example, the end portion of the cathode region 82 in the Y axis direction may be arranged between the well region 11 and the contact hole 54.

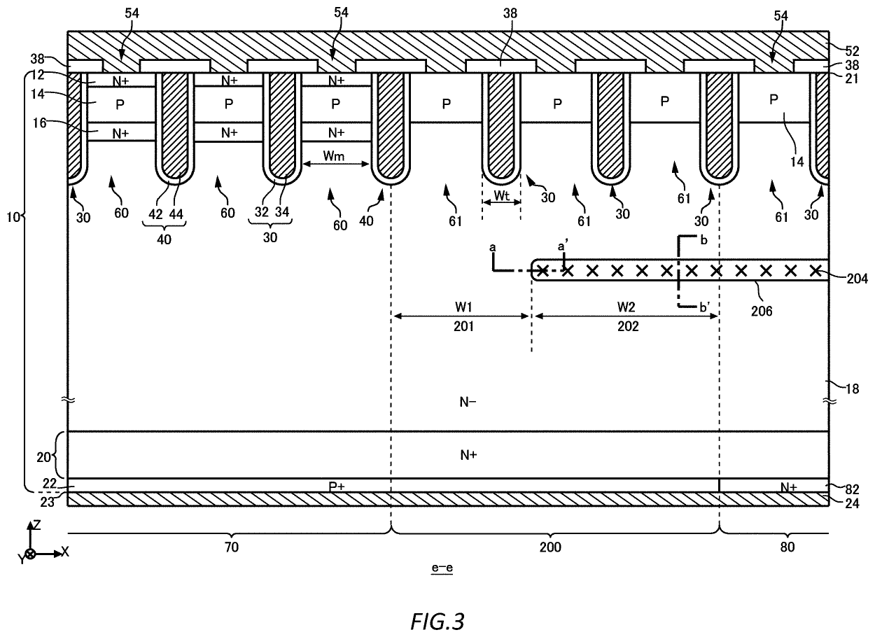

FIG. 3 illustrates a view showing an example of a cross section e-e in FIG. 2. The cross section e-e is an XZ plane passing through the emitter region 12 and the cathode region 82. The semiconductor device 100 of this example includes the semiconductor substrate 10, the interlayer dielectric film 38, the emitter electrode 52, and the collector electrode 24 in the cross section.

The interlayer dielectric film 38 is provided on the upper surface of the semiconductor substrate 10. The interlayer dielectric film 38 is a film including at least one layer of a dielectric film such as silicate glass to which an impurity such as boron or phosphorus is added, a thermal oxide film, and other dielectric films. The interlayer dielectric film 38 is provided with the contact hole 54 described in FIG. 2.

The emitter electrode 52 is provided above the interlayer dielectric film 38. The emitter electrode 52 is in contact with the upper surface 21 of the semiconductor substrate 10 through the contact hole 54 of the interlayer dielectric film 38. The collector electrode 24 is provided on the lower surface 23 of the semiconductor substrate 10. The emitter electrode 52 and the collector electrode 24 are formed of a metal material such as aluminum. In the present specification, the direction in which the emitter electrode 52 is connected to the collector electrode 24 (the Z axis direction) is referred to as the depth direction.

The semiconductor substrate 10 includes an N type or N− type drift region 18. The drift region 18 is provided in each of the transistor portion 70, the diode portion 80, and the boundary region 200.

In the mesa portion 60 of the transistor portion 70, the N+ type emitter region 12 and the P type base region 14 are provided in order from the upper surface 21 side of the semiconductor substrate 10. The drift region 18 is provided below the base region 14. The mesa portion 60 may be provided with an N+ type accumulation region 16. The accumulation region 16 is arranged between the base region 14 and the drift region 18.

The emitter region 12 is exposed on the upper surface 21 of the semiconductor substrate 10 and is provided in contact with the gate trench portion 40. The emitter region 12 may be in contact with the trench portions on both sides of the mesa portion 60. The emitter region 12 has a higher doping concentration than the drift region 18.

The base region 14 is provided below the emitter region 12. The base region 14 of this example is provided in contact with the emitter region 12. The base region 14 may be in contact with the trench portions on both sides of the mesa portion 60.

The accumulation region 16 is provided below the base region 14. The accumulation region 16 is an N+ type region having a higher doping concentration than the drift region 18. That is, the accumulation region 16 has a higher donor concentration than the drift region 18. By providing the accumulation region 16 having the high concentration between the drift region 18 and the base region 14, it is possible to improve a carrier injection enhancement effect (IE effect) and reduce an on-voltage. The accumulation region 16 may be provided to entirely cover a lower surface of the base region 14 in each mesa portion 60.

The mesa portion 61 of the diode portion 80 and the boundary region 200 is provided with the P type base region 14 in contact with the upper surface 21 of the semiconductor substrate 10. The drift region 18 is provided below the base region 14. In the mesa portion 61, the accumulation region 16 may be provided below the base region 14.

In each of the transistor portion 70, the diode portion 80, and the boundary region 200, an N+ type buffer region 20 may be provided below the drift region 18. The doping concentration of the buffer region 20 is higher than the doping concentration of the drift region 18. The buffer region 20 may have a concentration peak having a higher doping concentration than the drift region 18. The doping concentration of the concentration peak refers to a doping concentration at a local maximum of the concentration peak. Further, as the doping concentration of the drift region 18, an average value of doping concentrations in a region where the doping concentration distribution is substantially flat may be used.

The buffer region 20 may have two or more concentration peaks in the depth direction (the Z axis direction) of the semiconductor substrate 10. The concentration peak of the buffer region 20 may be provided at the same depth position as, for example, a chemical concentration peak of hydrogen (proton) or phosphorus. The buffer region 20 may function as a field stopper layer which prevents a depletion layer expanding from the lower end of the base region 14 from reaching the collector region 22 of the P+ type and the cathode region 82 of the N+ type.

In the transistor portion 70, the collector region 22 of the P+ type is provided below the buffer region 20. An acceptor concentration of the collector region 22 is higher than an acceptor concentration of the base region 14. The collector region 22 may include an acceptor which is the same as or different from an acceptor of the base region 14. The acceptor of the collector region 22 is, for example, boron.

Below the buffer region 20 in the diode portion 80, the cathode region 82 of the N+ type is provided. A donor concentration of the cathode region 82 is higher than a donor concentration of the drift region 18. A donor of the cathode region 82 is, for example, hydrogen or phosphorus. Note that an element serving as a donor and an acceptor in each region is not limited to the example described above.

In the boundary region 200, the collector region 22 of the P+ type is provided below the buffer region 20. The collector region 22 of the boundary region 200 may have the same doping concentration as the collector region 22 of the transistor portion 70. A boundary position between the cathode region 82 and the collector region 22 in the X axis direction is set as a boundary position between the diode portion 80 and the boundary region 200 in the X axis direction. Further, of the gate trench portions 40 in contact with the emitter regions 12, the gate trench portion 40 arranged closest to the diode portion 80 in the X axis direction is set as a boundary position between the transistor portion 70 and the boundary region 200 in the X axis direction. A center position of the gate trench portion 40 in the X axis direction may be set as the boundary position between the transistor portion 70 and the boundary region 200 in the X axis direction. Of the two trench portions in contact with the emitter region 12 arranged closest to the diode portion 80 in the X axis direction, the trench portion on the diode portion 80 side may be the dummy trench portion 30. The dummy trench portion 30 in this case may be the boundary position between the transistor portion 70 and the boundary region 200 in the X axis direction. For example, in the boundary region 200, the structure of the mesa portion 61 arranged in the upper surface 21 side of the semiconductor substrate 10 is the same as that of the diode portion 80, and the structure in the lower surface 23 side (the collector region 22 and the buffer region 20 in this example) is the same as that of the transistor portion 70.

The boundary region 200 may alternatively be provided with the emitter region 12. Note that in that case, the boundary region 200 is not provided with the gate trench portion 40. Moreover, the trench portion at the boundary position between the transistor portion 70 and the boundary region 200 is the dummy trench portion 30. In other words, transistor operations do not occur in the boundary region 200. The boundary region 200 may alternatively be provided with the gate trench portion 40. Note that in that case, the boundary region 200 is not provided with the emitter region 12. In other words, transistor operations do not occur in the boundary region 200.

The collector region 22 and the cathode region 82 are exposed on the lower surface 23 of the semiconductor substrate 10 and are connected to the collector electrode 24. The collector electrode 24 may be in contact with the entire lower surface 23 of the semiconductor substrate 10. The emitter electrode 52 and the collector electrode 24 are formed of a metal material such as aluminum.

One or more gate trench portions 40 and one or more dummy trench portions 30 are provided on the upper surface 21 side of the semiconductor substrate 10. Each trench portion passes through the base region 14 from the upper surface 21 of the semiconductor substrate 10, and is provided to below the base region 14. In a region where at least any one of the emitter region 12, the contact region 15, or the accumulation region 16 is provided, each trench portion also passes through the doping regions of these. The configuration of the trench portion passing through the doping region is not limited to that manufactured in the order of forming the doping region and then forming the trench portion. A configuration in which the trench portion is formed and then the doping region is formed between the trench portions is also included in the configuration in which the trench portion passes through the doping region.

As described above, the transistor portion 70 is provided with the gate trench portion 40 and the dummy trench portion 30. The diode portion 80 and the boundary region 200 of this example are provided with the dummy trench portion 30, and are not provided with the gate trench portion 40. Note that the gate trench portion 40 may be arranged or the dummy trench portion 30 may be arranged at the boundary between the boundary region 200 and the transistor portion 70.

The gate trench portion 40 includes a gate trench, a gate dielectric film 42, and a gate conductive portion 44 provided on the upper surface 21 of the semiconductor substrate 10. The gate dielectric film 42 is provided to cover the inner wall of the gate trench. The gate dielectric film 42 may be formed by oxidizing or nitriding a semiconductor on the inner wall of the gate trench. The gate conductive portion 44 is provided on an inner side of the gate dielectric film 42 inside the gate trench. That is, the gate dielectric film 42 insulates the gate conductive portion 44 from the semiconductor substrate 10. The gate conductive portion 44 is formed of a conductive material such as polysilicon.

The gate conductive portion 44 may be provided longer than the base region 14 in the depth direction. The gate trench portion 40 in the cross section is covered by the interlayer dielectric film 38 on the upper surface 21 of the semiconductor substrate 10. The gate conductive portion 44 is electrically connected to the gate runner. When a predetermined gate voltage is applied to the gate conductive portion 44, a channel is formed by an electron inversion layer in a surface layer of the base region 14 at a boundary in contact with the gate trench portion 40.

The dummy trench portions 30 may have the same structure as the gate trench portions 40 in the cross section. The dummy trench portion 30 includes a dummy trench, a dummy dielectric film 32, and a dummy conductive portion 34 provided on the upper surface 21 of the semiconductor substrate 10. The dummy conductive portion 34 is electrically connected to the emitter electrode 52. The dummy dielectric film 32 is provided to cover an inner wall of the dummy trench. The dummy conductive portion 34 is provided inside the dummy trench, and is provided on an inner side of the dummy dielectric film 32. The dummy dielectric film 32 insulates the dummy conductive portion 34 from the semiconductor substrate 10. The dummy conductive portion 34 may be formed of the same material as the gate conductive portion 44. For example, the dummy conductive portion 34 is formed of a conductive material such as polysilicon. The dummy conductive portion 34 may have the same length as the gate conductive portion 44 in the depth direction.

The gate trench portion 40 and the dummy trench portion 30 of this example are covered by the interlayer dielectric film 38 on the upper surface 21 of the semiconductor substrate 10. Note that the bottoms of the dummy trench portion 30 and the gate trench portion 40 may be formed in a curved-surface shape (a curved shape in the cross section) convexly downward.

The semiconductor device 100 of this example includes a lifetime adjustment region 206 containing a lifetime killer that adjusts a lifetime of carriers. The lifetime adjustment region 206 of this example is a region where a lifetime of charge carriers is locally small. The charge carriers are electrons or holes. The charge carriers may simply be referred to as carriers.

By implanting charged particles of helium or the like into the semiconductor substrate 10, lattice defects 204 such as vacancies are formed in the vicinity of the implantation position. The lattice defect 204 generates a recombination center. The lattice defects 204 may be mainly composed of vacancies such as monatomic vacancies (V) and diatomic vacancies or divacancies (VV), may be dislocations, may be interstitial atoms, or may be transition metals or the like. For example, atoms adjacent to the vacancies have dangling bonds. In a broad sense, the lattice defects 204 may also include donors and acceptors. However, in the present specification, the lattice defects 204 mainly composed of vacancies may be referred to as vacancy-type lattice defects, vacancy-type defects, or simply lattice defects. In the present specification, the lattice defect 204 may be simply referred to as a recombination center or a lifetime killer as a recombination center contributing to the carrier recombination. The lifetime killer may be formed by implanting helium ions into the semiconductor substrate 10. A density of the lattice defect 204 may be used as a helium chemical concentration. Note that the lifetime killer formed by implanting helium may be terminated by hydrogen existing in the buffer region 20, so a depth position of the density peak of the lifetime killer and a depth position of the helium chemical concentration peak may not match. In addition, when implanting hydrogen ions into the semiconductor substrate 10, the lifetime killer may be formed in a passed-through region of hydrogen ions that is more on the implantation surface side than the projected range.

The lattice defect 204 is an example of the lifetime killer. In FIG. 3, the lattice defects 204 at the implantation position of charged particles are schematically indicated by X marks. Since carriers are captured by the lattice defects 204 in a region where many lattice defects 204 remain, the lifetime of carriers becomes short. By adjusting the lifetime of carriers, characteristics of the diode portion 80 such as a reverse recovery time and a reverse recovery loss can be adjusted. A position at which the carrier lifetime shows a local minimum value in the depth direction of the semiconductor substrate 10 may be set as the depth position of the lifetime adjustment region 206.

The lifetime adjustment region 206 is arranged in the upper surface 21 side of the semiconductor substrate 10. The upper surface 21 side is a region from a center position of the semiconductor substrate 10 in the depth direction to the upper surface 21 of the semiconductor substrate 10. The lifetime adjustment region 206 of this example is arranged below the lower end of the trench portion.

The lifetime adjustment region 206 is provided in the diode portion 80. The lifetime adjustment region 206 may be provided across the entire diode portion 80 in the X axis direction. The lifetime adjustment region 206 is also provided in a part of the boundary region 200. In the boundary region 200, a region where the lifetime adjustment region 206 is not provided is a first portion 201, and a region where the lifetime adjustment region 206 is provided is a second portion 202. The first portion 201 is a region where the carrier lifetime at the same depth position as the lifetime adjustment region 206 is shorter than the carrier lifetime of the lifetime adjustment region 206 in the diode portion 80. The first portion 201 may be a region not implanted with charged particles of helium or the like for forming the lifetime killer such as the lattice defect 204. A chemical concentration (km 3) of charged particles of helium or the like in the first portion 201 may be the same as the chemical concentration of the charged particles at the center of the drift region 18 in the Z axis direction.

The first portion 201 is in contact with the transistor portion 70 in the X axis direction. A width of the first portion 201 in the X axis direction is represented by W1. The second portion 202 is in contact with the diode portion 80 in the X axis direction. A width of the second portion 202 in the X axis direction is represented by W2. The lifetime adjustment region 206 of the second portion 202 is a region to which the lifetime adjustment region 206 of the diode portion 80 extends in the X axis direction. The lifetime adjustment region 206 of the boundary region 200 may be provided at the same depth position as the lifetime adjustment region 206 of the diode portion 80. The first portion 201 and the second portion 202 are in contact with each other in the X axis direction. A width of the boundary region 200 in the X axis direction is represented by W1+W2.

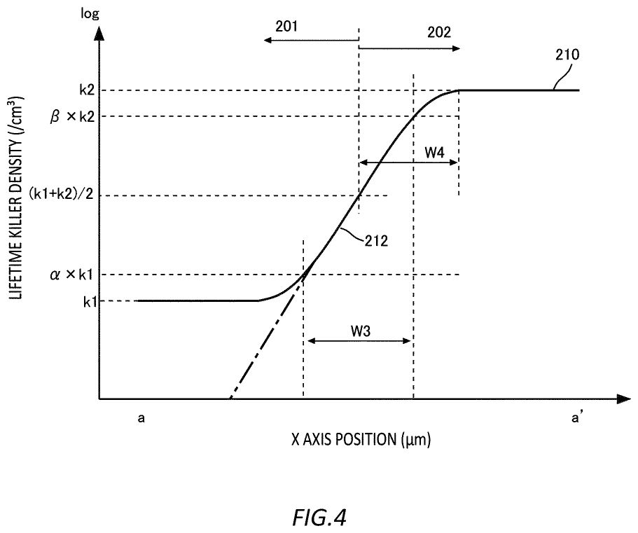

FIG. 4 shows an example of a lifetime killer density distribution 210 on a line a-a′ of FIG. 3. As described above, the lifetime killer of this example is the lattice defect 204. The line a-a′ is a straight line that passes through the vicinity of the boundary between the first portion 201 and the second portion 202 and is parallel to the X axis, the depth position thereof being the same as that of the lifetime adjustment region 206.

The density of the lifetime killer in the first portion 201 is represented by k1. As the density k1, a minimum value of the lifetime killer density of the first portion 201 at the depth may be used, or an average value may be used. The density of the lifetime killer in the second portion 202 is represented by k2. As the density k2, a maximum value of the lifetime killer density of the second portion 202 at the depth may be used, or an average value may be used. The density k2 is larger than the density k1. A position at which the lifetime killer density becomes an average value of k1 and k2 (that is, (k1+k2)/2) may be set as a boundary position between the first portion 201 and the second portion 202 in the X axis direction. When the minimum value of the lifetime killer density is equal to or smaller than a detection lower limit in the measurement by SIMS described above or the like, the density k1 may be set as the detection lower limit concentration. When the lifetime killer density continues to decrease as indicated by the dashed-dotted line in FIG. 4 and the minimum value of the lifetime killer density cannot be measured, the density k1 may take a value that is 1% of the density k2, may take a value that is 0.1% of the density k2, or may be defined as 0.01% of the density k2, for example. The density k1 may be similarly defined also when the minimum value of the lifetime killer density is equal to or smaller than the detection lower limit in the measurement by SIMS described above or the like.

The density distribution 210 in the X axis direction has a lateral slope 212 where the lifetime killer density decreases from the second portion 202 toward the first portion 201. The lateral slope 212 is a portion where the lifetime killer density continuously decreases from k2 to k1. In other words, the lateral slope 212 does not have a portion where the lifetime killer density increases in a direction from the second portion 202 toward the first portion 201.

A width of the lateral slope 212 in the X axis direction is represented by W3. The width W3 may be a width of a portion where the lifetime killer density decreases from 13×k2 to a×k1. 13 may be 1, or may be a value smaller than 1. When a position at which the lifetime killer density starts to decrease from k2 is indefinite, β may take a value smaller than 1 (for example, 0.9). α may be 1, or may be a value larger than 1. When a position at which the lifetime killer density converges to k1 is indefinite, a may take a value larger than 1 (for example, 1.1). A value that is 2 times a width W4 of a portion where the lifetime killer density decreases from k2 to an average value of k1 and k2 may be set as the width of the lateral slope 212 in the X axis direction.

The width W1 of the first portion 201 described in FIG. 3 is smaller than the width W2 of the second portion 202. That is, W1<W2 is established. Accordingly, a portion where the lifetime adjustment region 206 is to be provided in the boundary region 200 can be enlarged. Thus, it is possible to suppress a flow of carriers from the transistor portion 70 to the diode portion 80 and reduce a reverse recovery loss of the diode portion 80. The width W1 may be half or less or ¼ or less of the width W2.

The width W1 of the first portion 201 is equal to or larger than the width of the lateral slope 212 (for example, W3). Accordingly, an effect of the lifetime adjustment region 206 on a threshold voltage of the transistor portion 70 and the like can be reduced. The lifetime killer such as the lattice defect 204 can be formed by partially irradiating charged particles of helium or the like onto the semiconductor substrate 10 using a mask or the like. Accordingly, the lifetime adjustment region 206 can be formed in a region not covered by the mask. On the other hand, charged particles may also spread below the mask in the vicinity of the end portion of the mask. Thus, also in the region covered by the mask, the lifetime killer is formed within a predetermined range from the end portion of the mask. Thus, the lifetime killer density distribution 210 in the X axis direction has the lateral slope 212.

In this example, by setting the width W1 of the first portion 201 to be equal to or larger than the width of the lateral slope 212, the lateral slope 212 is prevented from reaching the transistor portion 70. Thus, it is possible to suppress formation of the lifetime killer in the transistor portion 70 and suppress a variation of the threshold voltage and the like. The width W1 may be 2 times or more, 5 times or more, or 10 times or more of the width of the lateral slope 212.

As shown in FIG. 3, a width of the mesa portion 60 of the transistor portion 70 in the X axis direction is represented by Wm. The width of the mesa portion 60 of the transistor portion 70 may be constant. When the width of the mesa portion 60 of the transistor portion 70 is not constant, the width of the mesa portion 60 closest to the boundary region 200 is set as the width Wm of the mesa portion 60. The width W1 of the first portion 201 may be larger than the width Wm of the mesa portion 60. The width W1 of the first portion 201 may be 2 times or more or 3 times or more of the width Wm of the mesa portion 60. The first portion 201 may include one or more mesa portions 61 or a plurality of mesa portions 61.

As shown in FIG. 3, a width in an array direction in which the plurality of trench portions are arrayed (the X axis direction) is represented by Wt. The width Wt may be the width of the gate trench portion 40, or may be the width of the dummy trench portion 30. The width Wt may be the width of the trench portion in the upper surface 21, may be the width at half the depth position of the depth of the trench portion in the depth direction (the Z axis direction), or may be the largest width of the trench portion. In this example, the width Wt is the largest width of the trench portion. The width W1 of the first portion 201 may be larger than a width (Wt+2Wm) obtained by adding the width Wt of at least one trench portion in the boundary region 200 and the width of two mesa portions sandwiching the trench portion (2×Wm). The width Wt of the trench portion in this case may be the width Wt of the dummy trench portion 30, or may be the width Wt of the gate trench portion 40. The width Wt of the trench portion may be a maximum value, minimum value, or average value of the widths Wt of the one or more trench portions in the boundary region 200. The width Wt of the trench portion may be a maximum value, minimum value, or average value of the widths Wt of the one or more trench portions in the first portion 201.

Accordingly, an effect of the lifetime adjustment region 206 on the transistor portion 70 can be reduced. Further, by setting the width W1 of the first portion 201 to be 2 times or more of the width Wm of the mesa portion 60, it becomes easy to maintain a carrier concentration in the mesa portion 60 of the transistor portion 70 closest to the boundary region 200, and a decrease of the carrier concentration toward the boundary region 200 is suppressed. Accordingly, a decrease of an on-voltage of IGBT in the mesa portion 60 can be suppressed. Furthermore, by setting the width W1 of the first portion 201 to be larger than the width (Wt+2Wm) obtained by adding the width Wt of at least one trench portion in the boundary region 200 and the width of two mesa portions sandwiching the trench portion (2×Wm), it becomes easy to maintain the carrier concentration in the mesa portion 60 of the transistor portion 70 closest to the boundary region 200, and a decrease of the carrier concentration toward the boundary region 200 is suppressed. Accordingly, a decrease of an on-voltage of IGBT in the mesa portion 60 can be suppressed.

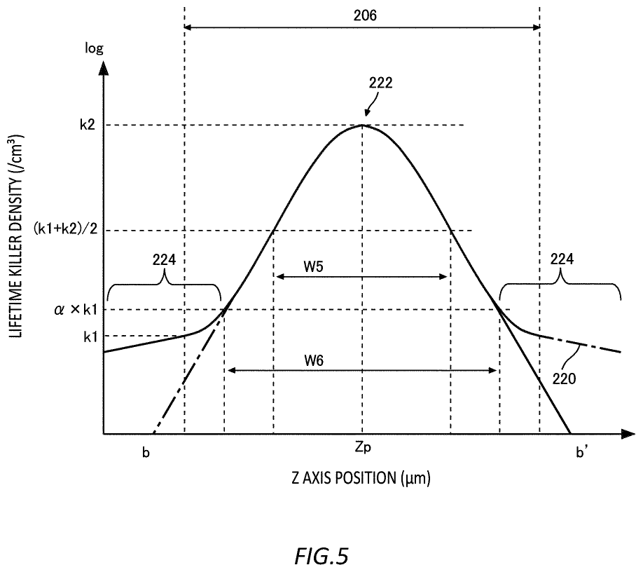

FIG. 5 shows an example of the lifetime killer density distribution 220 on a line b-b′ of FIG. 3. The line b-b′ is a straight line that passes through the lifetime adjustment region 206 in the second portion 202 and is parallel to the Z axis.

In the second portion 202, the density distribution 220 has a density peak 222. The density peak 222 is a portion including a depth position Zp at which the lifetime killer density shows the local maximum value k2. The density peak 222 may be a portion where the density distribution is in a shape of a mountain. When charged particles of helium or the like are irradiated at the depth position Zp, many lifetime killers are formed at the depth position Zp. Further, due to a variation in the projected range of charged particles, the density peak 222 having a local maximum arranged at the depth position Zp is formed in the density distribution 220. The density distribution 210 shown in FIG. 4 is a lifetime killer density distribution in the X axis direction at the depth position Zp.

The lifetime killer density distribution 220 in a case where the implantation surface of charged particles of helium or the like is the upper surface 21 is indicated by a solid line, and the lifetime killer density distribution 220 in a case where the implantation surface is the lower surface 23 is indicated by a dashed-dotted line. Due to the difference in the implantation surface, the lifetime killer density distribution 220 in the Z axis direction may become asymmetric with respect to the depth position Zp as a center. When the implantation surface is the upper surface 21, the lifetime killer density distribution 220 in the Z axis direction shows a distribution that has a tail 224 in the −Z direction (the upper surface 21 side) and has a precipitous decrease in the +Z direction (the lower surface 23 side). When the implantation surface is the lower surface 23, the lifetime killer density distribution 220 in the Z axis direction shows a distribution that has the tail 224 in the +Z direction (the lower surface 23 side) and has a precipitous decrease in the −Z direction (the upper surface 21 side). The density k1 may or may not match with a value of the density of the tail 224 of the lifetime killer density distribution in the implantation surface side as in this example.

A width of the density peak 222 in the Z axis direction (a peak width) is represented by W5. A full width at half maximum of the density peak 222 may be the peak width W5. In another example, a width W6 of a portion where the lifetime killer density becomes α× k1 or more in the density peak 222 may be set as the peak width of the density peak 222. α may be 1, or may be a value larger than 1. α is, for example, 1.1. When a value of the density of the tail 224 of the lifetime killer density distribution in the implantation surface side is larger than the density k1, the lifetime killer density α×k1 may be set to become larger than the value of the density of the tail 224 of the lifetime killer density distribution. Note that in this case, the lifetime killer density α×k1 is set to become smaller than the density k2.

The width W1 of the first portion 201 described in FIG. 3 may be equal to or larger than the peak width of the density peak 222 (for example, W5). As the peak width of the density peak 222 becomes larger, the variation in the width of the lateral slope 212 described in FIG. 4 tends to become larger. By setting the width W1 to be equal to or larger than the peak width of the density peak 222, a situation where the lateral slope 212 reaches the transistor portion 70 can be suppressed even when the variation in the width of the lateral slope 212 is caused. The width of the lateral slope 212 may be smaller than the peak width of the density peak 222. The width W1 of the first portion 201 may be 2 times or more, 5 times or more, or 10 times or more of the peak width of the density peak 222. The width W1 of the first portion 201 may be equal to or larger than the width W6 of the density peak 222.

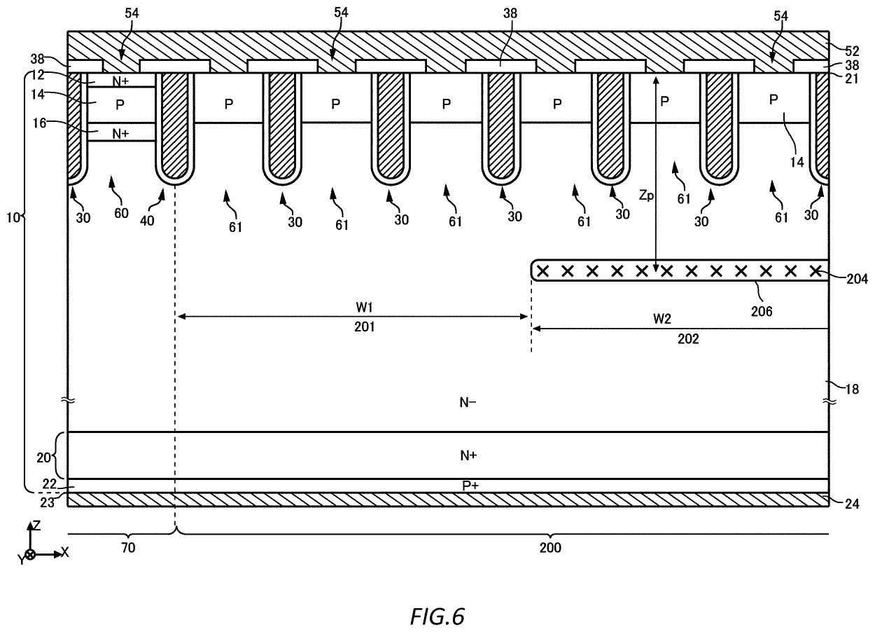

FIG. 6 illustrates a view showing another configuration example of the boundary region 200. The cross section shown in FIG. 6 is an XZ plane including the first portion 201 and a portion of the second portion 202. The boundary region 200 of this example includes more mesa portions 61 than the boundary region 200 shown in FIG. 3. As described in FIG. 5, a distance from the upper surface 21 of the semiconductor substrate 10 to the local maximum of the density peak 222 in the Z axis direction is represented by Zp. The width W1 of the first portion 201 may be equal to or larger than the distance Zp. As the distance Zp becomes larger, the variation in the width of the lateral slope 212 described in FIG. 4 tends to become larger. By setting the width W1 to be equal to or larger than the distance Zp, a situation where the lateral slope 212 reaches the transistor portion 70 can be suppressed even when the variation in the width of the lateral slope 212 is caused. The width of the lateral slope 212 may be smaller than the distance Zp. The width W1 of the first portion 201 may be 1.5 times or more, 2 times or more, or 3 times or more of the distance Zp.

The width W2 of the second portion 202 may be equal to or larger than the distance Zp. Accordingly, it is possible to secure an area of the second portion 202 and suppress a flow of carriers from the transistor portion 70 to the diode portion 80. The width W2 may be 2 times or more, 5 times or more, 10 times or more, or 15 times or more of the distance Zp. The width W1 of the first portion 201 may be larger than the width W2 of the second portion 202. The width W1 of the first portion 201 may be 2 times or more, 5 times or more, 10 times or more, or 15 times or more of the width W2 of the second portion 202.

In each example described in the present specification, the width W1 of the first portion 201 may be 1 μm or more. By setting the width W1 to be 1 μm or more, an effect that the variation of the threshold voltage at which the transistor portion 70 is set to an on state is suppressed was obtained. The width W1 may be 5 μm or more, 10 μm or more, or 20 μm or more. By increasing the width W1, it becomes easier to suppress the variation of the threshold voltage. Note that if the width W1 becomes too large, the effect that the variation of the threshold voltage is suppressed is saturated, but the semiconductor device 100 becomes large. The width W1 may be 200 μm or less. The width W1 may be 150 μm or less, 100 μm or less, 50 μm or less, or 30 μm or less. In addition, the width W1+W2 of the boundary region 200 may be 200 μm or less. The width W1+W2 may be 150 μm or less or 100 μm or less. The width W1+W2 may be 30 μm or more, 50 μm or more, 70 μm or more, or 100 μm or more.

The width W1 of the first portion 201 may be 10% or more of the width W1+W2 of the boundary region 200. The width W1 may be 20% or more or 30% or more of the width W1+W2. The width W1 may be 50% or less, 40% or less, or 30% or less of the width W1+W2. Accordingly, it is possible to secure the area of the second portion 202 and suppress a flow of carriers from the transistor portion 70 to the diode portion 80.

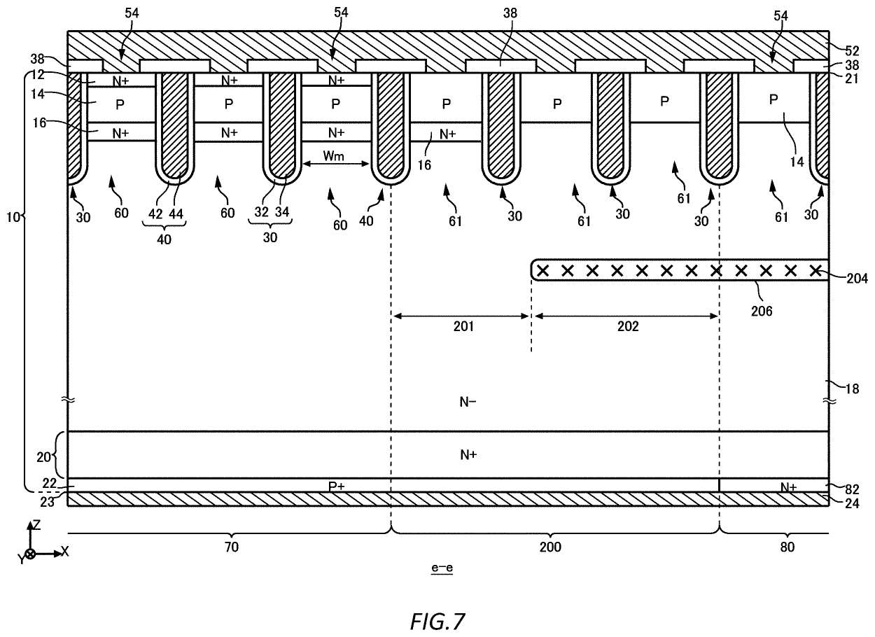

FIG. 7 illustrates a view showing another example of the cross section e-e. In the semiconductor device 100 of this example, the arrangement of the accumulation region 16 is different from that of other examples described in the present specification. Structures of the semiconductor device 100 other than the accumulation region 16 are similar to those of any of the examples described in the present specification.

The accumulation region 16 of this example is also arranged in at least some of the mesa portions 61 of the first portion 201. The accumulation region 16 may be arranged in one or more mesa portions 61 closest to the transistor portion 70 out of the mesa portions 61 of the first portion 201. In this example, the accumulation region 16 is not provided in the second portion 202. The accumulation region 16 and the lifetime adjustment region 206 do not overlap with each other in a top view. The accumulation region 16 and the lifetime adjustment region 206 may be in contact with each other or may be set apart from each other in the top view.

By arranging the accumulation region 16 in the mesa portion 61 in the vicinity of the transistor portion 70, it becomes easy to raise the carrier concentration in the mesa portion 60 arranged in the vicinity of the end portion of the transistor portion 70 and to obtain an IE effect. Since the accumulation region 16 is not provided in the second portion 202, an effect of providing the accumulation region 16 in the boundary region 200, on the diode portion 80, such as an increase of an electric field intensity during reverse recovery, for example, can be suppressed.

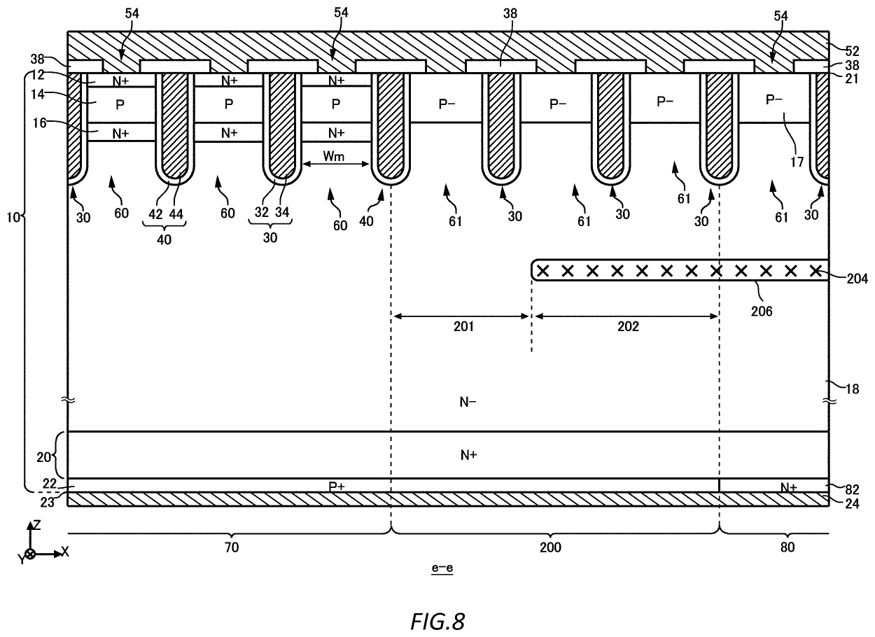

FIG. 8 illustrates a view showing another example of the cross section e-e. In the semiconductor device 100 of this example, the structure of the mesa portion 61 is different from that of the other examples described in the present specification. Structures of the semiconductor device 100 other than the mesa portion 61 are similar to those of any of the examples described in the present specification. The diode portion 80 and the boundary region 200 may include the mesa portions 61 having the same structure.

The mesa portion 61 of this example includes an anode region 17 in place of the base region 14. Structures other than the anode region 17 are similar to those of the mesa portion 61 of the other examples described in the present specification. The anode region 17 is a P type region having a doping concentration different from that of the base region 14. In the example of FIG. 8, the anode region 17 is a P− type region having a lower doping concentration than the base region 14.

By adjusting the doping concentration of the anode region 17 to be lower than the doping concentration of the base region 14, a carrier injection amount from the anode region 17 can be adjusted to be relatively small. The doping concentration of the anode region 17 may be adjusted according to the lifetime killer density in the lifetime adjustment region 206. For example, by setting the lifetime killer density in the lifetime adjustment region 206 low, an effect of the lifetime adjustment region 206 on the transistor portion 70 can be suppressed. However, with a low lifetime killer density, the carrier lifetime in the diode portion 80 may be unable to be reduced sufficiently. In this case, the doping concentration of the anode region 17 may be lowered to thus lower the carrier injection amount from the anode region 17.

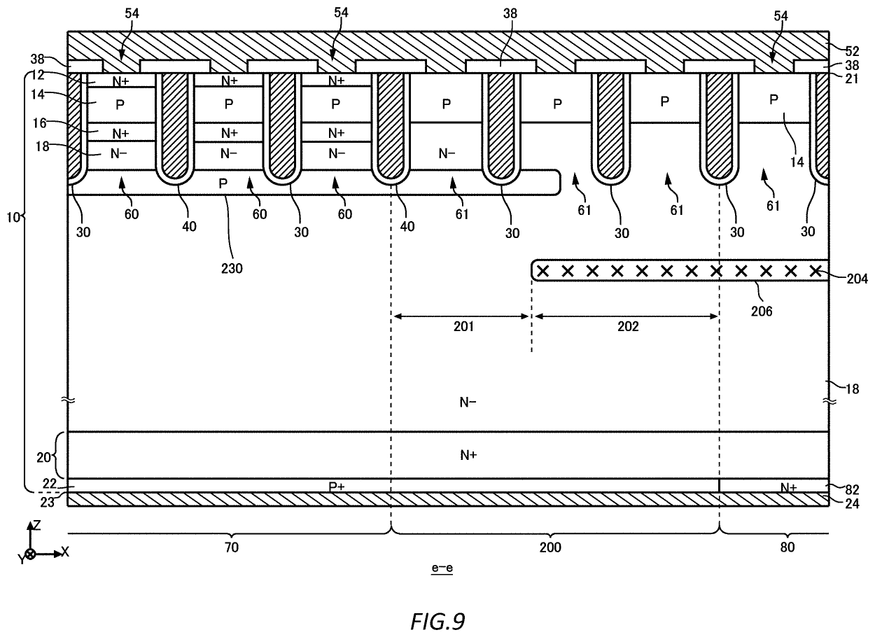

FIG. 9 illustrates a view showing another example of the cross section e-e. The semiconductor device 100 of this example is different from that of the other examples described in the present specification in that a lower end region 230 is provided. Structures of the semiconductor device 100 other than the lower end region 230 are similar to those of any of the examples described in the present specification.

The lower end region 230 is a P type region provided in contact with a lower end of at least the trench portion closest to the boundary region 200 out of the plurality of trench portions of the transistor portion 70. The lower end region 230 may have a lower doping concentration than the base region 14, or may have a lower doping concentration than the anode region 17. The lower end region 230 is a floating region not in contact with the emitter electrode 52.

In the example of FIG. 9, the trench portion closest to the boundary region 200 is the gate trench portion 40 arranged at the boundary position between the transistor portion 70 and the boundary region 200. By providing the lower end region 230, it is possible to relax an electric field strength in the vicinity of the lower end of the trench portion and improve a breakdown voltage of the semiconductor device 100.

The lower end region 230 may be provided continuously across the plurality of trench portions in the transistor portion 70. In the example of FIG. 9, the lower end region 230 is provided continuously across all of the trench portions of the transistor portion 70. In the transistor portion 70, the lower end region 230 is arranged apart from the base region 14. An N type region is arranged between the base region 14 and the lower end region 230. The N type region may be at least one of the accumulation region 16 or the drift region 18. In the example of FIG. 9, the accumulation region 16, the drift region 18, and the lower end region 230 are arranged below the base region in order. A distance between the lower end region 230 and the upper surface 21 is smaller than a distance between the lifetime adjustment region 206 and the upper surface 21. That is, the lower end region 230 is arranged at a position higher than the lifetime adjustment region 206.

The lower end region 230 may also be arranged in the boundary region 200. The lower end region 230 of this example is provided to extend from the transistor portion 70 to the second portion 202 in the X axis direction. In the X axis direction, the lower end region 230 may be terminated inside the second portion 202. That is, the lower end region 230 does not need to be provided in the diode portion 80. In the top view, the lower end region 230 and the lifetime adjustment region 206 are arranged so as to partially overlap with each other in the boundary region 200. By extending the lower end region 230 to the second portion 202, avalanche capability of the transistor portion 70 can be improved, and occurrence of avalanche breakdown in the transistor portion 70 can be suppressed.

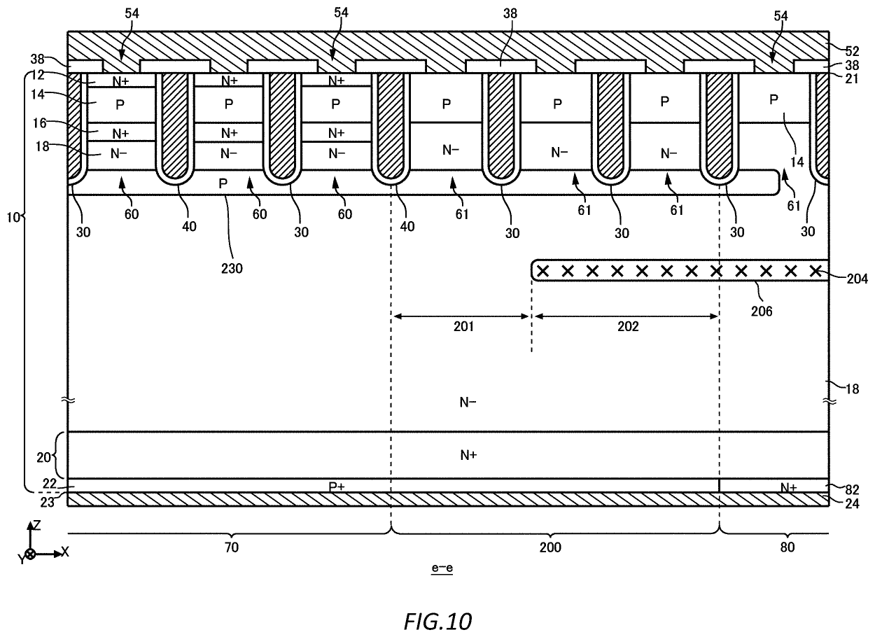

FIG. 10 illustrates a view showing another example of the cross section e-e. In the semiconductor device 100 of this example, the arrangement of the lower end region 230 is different from that of the example shown in FIG. 9. Structures of the semiconductor device 100 other than the lower end region 230 are similar to those of any of the examples described in the present specification.

The lower end region 230 of this example is provided to extend from the transistor portion 70 to the diode portion 80 in the X axis direction. In the X axis direction, the lower end region 230 may be terminated inside the diode portion 80. That is, the diode portion 80 includes a region where the lower end region 230 is not provided in the X axis direction. In the X axis direction, a width of a region of the diode portion 80 where the lower end region 230 is provided may be smaller than a width of a region of the diode portion 80 where the lower end region 230 is not provided. In the diode portion 80, the lower end region 230 may be arranged in only the mesa portion 61 arranged at the end portion in the X axis direction and does not need to be arranged in other mesa portions 61. By extending the lower end region 230 to the diode portion 80, avalanche capability of the transistor portion 70 can be improved, and occurrence of avalanche breakdown in the transistor portion 70 can be suppressed.

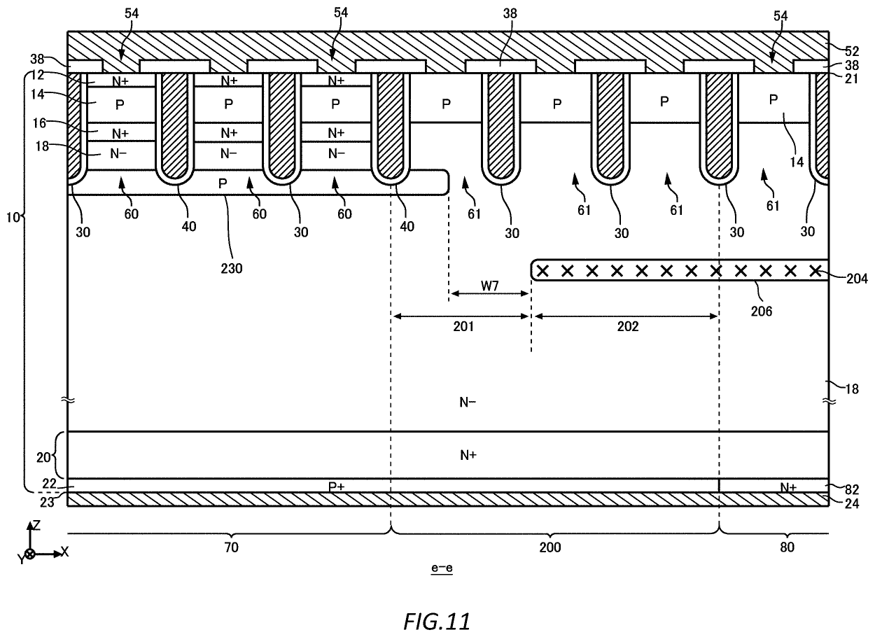

FIG. 11 illustrates a view showing another example of the cross section e-e. In the semiconductor device 100 of this example, the arrangement of the lower end region 230 is different from that of the examples shown in FIGS. 9 and 10. Structures of the semiconductor device 100 other than the lower end region 230 are similar to those of any of the examples described in the present specification.

The lower end region 230 of this example is provided to extend from the transistor portion 70 to the first portion 201 in the X axis direction. In this example, the lower end region 230 is terminated inside the first portion 201 in the X axis direction. That is, the lower end region 230 of this example is not provided in the second portion 202 and the diode portion 80. In the top view, the lower end region 230 and the lifetime adjustment region 206 do not overlap with each other. In the top view, the lower end region 230 and the lifetime adjustment region 206 may be in contact with each other, or may be set apart from each other.

When the lower end region 230 is extended to the boundary region 200, holes in the drift region 18 of the transistor portion 70 are easily extracted to the boundary region 200 through the lower end region 230. Thus, the IE effect of the transistor portion 70 is lowered. The holes are more easily extracted to the boundary region 200 as the lower end region 230 is extended more in the X axis direction, and thus, the IE effect of the transistor portion 70 is lowered. In this example, since the lower end region 230 is terminated in the first portion 201, the avalanche capability of the transistor portion 70 can be improved as described in FIG. 9 and the like while maintaining the IE effect of the transistor portion 70.

A distance between the lower end region 230 and the second portion 202 in the X axis direction is represented by W7. The distance W7 may be equal to or larger than the width of the lateral slope 212 (for example, W3) described in FIG. 4 and the like. The distance W7 may be 2 times or more, 5 times or more, or 10 times or more of the width of the lateral slope 212. The distance W7 may be equal to or larger than the mesa width Wm described in FIG. 3 and the like, or may be 2 times or more of the mesa width Wm.

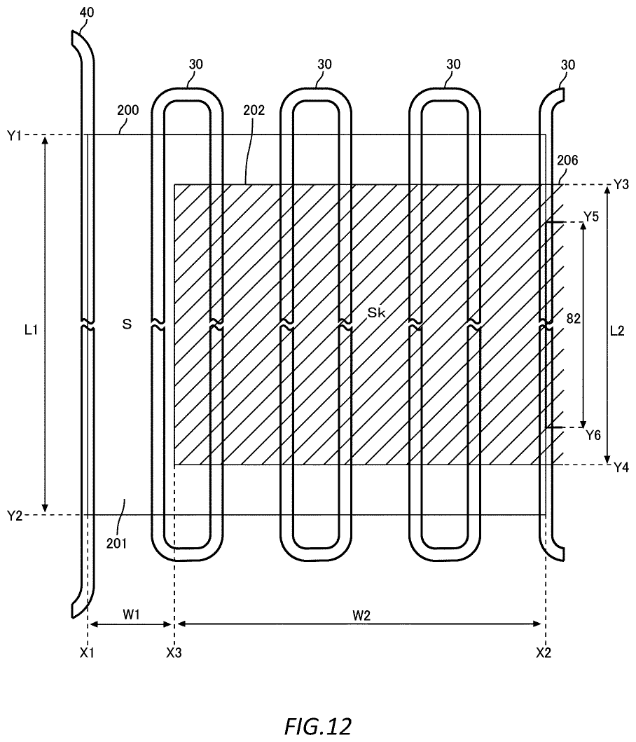

FIG. 12 illustrates a view showing an exemplary arrangement of the first portion 201 and the second portion 202 in the top view. FIG. 12 shows relative positions of the respective portions of the boundary region 200 with respect to the respective trench portions. In FIG. 12, a range where the boundary region 200 is provided is indicated by a rectangle in a solid line, and a range where the second portion 202 and the lifetime adjustment region 206 are provided is hatched with diagonal lines. A region not hatched with the diagonal lines in the boundary region 200 is the first portion 201.

In the example of FIG. 12, a boundary position between the transistor portion 70 and the boundary region 200 in the X axis direction is represented by X1, a boundary position between the diode portion 80 and the boundary region 200 in the X axis direction is represented by X2, and a boundary position between the first portion 201 and the second portion 202 in the X axis direction is represented by X3. Each boundary position is similar to that of the examples described in FIGS. 3 to 11.

In the example of FIG. 12, both end positions of the boundary region 200 in the Y axis direction are respectively represented by Y1 and Y2. The contact hole 54 shown in FIG. 2 and the like has a longitudinal length in the Y axis direction. In this example, end portion positions of the contact hole 54 in the Y axis direction are set as end portion positions of the boundary region 200 in the Y axis direction. When the end portion positions of the contact holes 54 provided in the plurality of mesa portions 61 in the Y axis direction are not constant, the end portion positions of the contact hole 54 that extends most outwardly in the Y axis direction may be set as the end portion positions of the boundary region 200 in the Y axis direction.

In the example of FIG. 12, both end positions of the second portion 202 in the Y axis direction are respectively represented by Y3 and Y4. The both end positions Y3 and Y4 of the second portion 202 are both end positions of the lifetime adjustment region 206 in the Y axis direction. At least one of the both end positions Y3 and Y4 may be arranged more on the inner side of the boundary region 200 than the both end positions Y1 and Y2 of the boundary region 200. In the example of FIG. 12, the second portion 202 is sandwiched by the first portion 201 in the Y axis direction. The both end positions Y3 and Y4 of the second portion 202 in the Y axis direction may be arranged more on the outer side than both end positions Y5 and Y6 of the cathode region 82 described in FIG. 2 and the like in the Y axis direction. That is, the lifetime adjustment region 206 in the diode portion 80 may be provided across a wider range than the cathode region 82 in the Y axis direction.

The area of the second portion 202 in the top view is represented by Sk, and the area of the boundary region 200 is represented by S. An area ratio Sk/S of the area Sk and the area S may satisfy the following expression.

0.8≤Sk/S<1

By setting the area ratio Sk/S to be 0.8 or more, it is possible to secure an area of the lifetime adjustment region 206 and suppress a flow of carriers from the transistor portion 70 to the diode portion 80. Further, a flow of carriers from a region arranged outside the second portion 202 in the Y axis direction to the diode portion 80 can be suppressed.

A distance between the position Y1 and the position Y3 or a distance between the position Y2 and the position Y4 may be larger than the width W1. The distance between the position Y1 and the position Y3 or the distance between the position Y2 and the position Y4 may be larger than the width W2. The distance between the position Y1 and the position Y3 and the distance between the position Y2 and the position Y4 may each be 0.3 (L1-L2) or more. As an example, the distance between the position Y1 and the position Y3 and the distance between the position Y2 and the position Y4 are each 0.5 (L1-L2). Accordingly, it is possible to prevent carriers from flowing from the first portion 201 to the diode portion 80 from the Y axis direction in particular via the second portion 202, and suppress a fall of reverse recovery capability, for example.

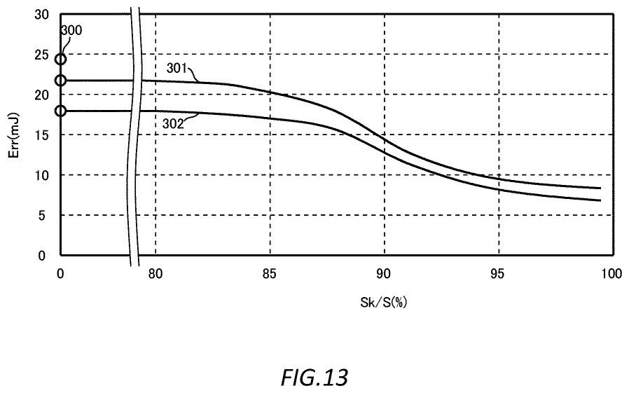

FIG. 13 illustrates a view showing a relationship between the area ratio Sk/S and a reverse recovery loss Err of the diode portion 80. If carriers flowing from the transistor portion 70 to the diode portion 80 are suppressed, a reverse recovery time of the diode portion 80 is shortened, and a reverse recovery loss can be reduced. FIG. 13 shows Comparative Example 300 in which the lifetime adjustment region 206 is not provided and Example 301 and Example 302 in which the lifetime adjustment region 206 is provided, in the structure shown in FIG. 3 and the like. In Example 302, a dose amount of charged particles that have been irradiated for forming the lifetime killer in the lifetime adjustment region 206 is 2 times the dose amount of Example 301. Further, the reverse recovery loss Err in a case where the lifetime adjustment region 206 is not provided in the boundary region 200 (that is, area ratio Sk/S=0) is indicated by a circle.

As shown in FIG. 13, when the area ratio Sk/S is 80% or more, the reverse recovery loss Err starts to decrease. The area ratio Sk/S may be 90% or more. As shown in FIG. 13, when the area ratio Sk/S is 90% or more, the reverse recovery loss Err largely decreases. The area ratio Sk/S may be 95% or more.

When the area ratio Sk/S is close to 100%, the effect of the decrease of the reverse recovery loss Err is saturated. The area ratio Sk/S may be 99.5% or less, 99% or less, 97% or less, or 95% or less. By setting the area ratio Sk/S small, it becomes easy to secure the width W1 of the first portion 201, and the variation of the threshold voltage of the transistor portion 70 can be suppressed.

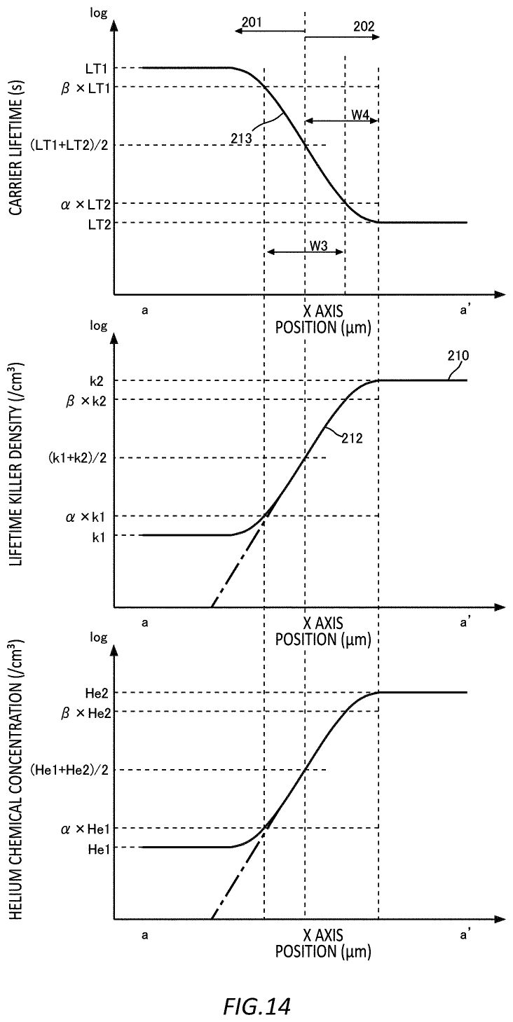

FIG. 14 illustrates a view showing a relationship among a lifetime killer density, a carrier lifetime, and a charged particle concentration in the lifetime adjustment region 206. The charged particles are impurities that have been irradiated for forming the lifetime killer such as the lattice defect 204. The charged particles of this example are helium ions.

In FIGS. 4, 5, and the like, the width of the lateral slope 212 (for example, W3), the peak width of the density peak 222 (for example, W5), and the depth position Zp of the density peak 222 have been determined from the lifetime killer density distribution. In another example, these values may be determined from a carrier lifetime (a vacancy lifetime in this example) distribution, or these values may be determined from a chemical density distribution of charged particles (for example, helium).

The carrier lifetime distribution may have a shape obtained by inverting the lifetime killer density distribution in a vertical axis direction. In other words, the carrier lifetime becomes shorter as the lifetime killer density becomes higher, and the carrier lifetime becomes longer as the lifetime killer density becomes lower. The carrier lifetime may be saturated at a sufficiently high value when the lifetime killer density is sufficiently low. The carrier lifetime saturated at a sufficiently high value may be referred to as a saturated carrier lifetime. The value of the saturated carrier lifetime may be 10 μs or more, 30 μs or more, 100 μs or more, or 300 μs or more. An upper limit value of the saturated carrier lifetime may be 10,000 μs or less, 3,000 μs or less, or 1,000 μs or less.

The carrier lifetime in the first portion 201 is represented by LT1. For the carrier lifetime LT1, a maximum value of the carrier lifetime of the first portion 201 at the depth position Zp may be used, or an average value may be used. The carrier lifetime in the second portion 202 is represented by LT2. For the carrier lifetime LT2, a minimum value of the carrier lifetime of the second portion 202 at the depth may be used, or an average value may be used.

The chemical concentration distribution of charged particles (for example, helium) may have a shape similar to that of the lifetime killer density distribution. In other words, the lifetime killer density becomes higher as the chemical concentration distribution of charged particles becomes higher, and the lifetime killer density becomes lower as the chemical concentration distribution of charged particles becomes lower.

The chemical concentration of charged particles in the first portion 201 is represented by He1. For the chemical concentration He1, a minimum value of the chemical concentration of charged particles of the first portion 201 at the depth position Zp may be used, or an average value may be used. The chemical concentration in the second portion 202 is represented by He2. For the chemical concentration He2, a maximum value of the chemical concentration of charged particles of the second portion 202 at the depth may be used, or an average value may be used.

The density k1 may be replaced with the carrier lifetime LT2 and the density k2 may be replaced with the carrier lifetime LT1 in the operations described in FIGS. 4, 5, and the like, to thus determine the width of the lateral slope 212 (for example, W3), the peak width of the density peak 222 (for example, W5), and the depth position Zp of the density peak 222. The density k1 may be replaced with the chemical concentration He1 and the density k2 may be replaced with the chemical concentration He2 in the operations described in FIGS. 4, 5, and the like, to thus determine the width of the lateral slope 212 (for example, W3), the peak width of the density peak 222 (for example, W5), and the depth position Zp of the density peak 222.

In FIG. 14, an example of calculating the width of the lateral slope 212 (for example, W3) from the carrier lifetime distribution will be described. The carrier lifetime LT1 is larger than the carrier lifetime LT2. A position at which the carrier lifetime becomes an average value of LT1 and LT2 (that is, (LT1+LT2)/2) may be set as the boundary position between the first portion 201 and the second portion 202 in the X axis direction.

The carrier lifetime distribution in the X axis direction has a lateral slope 213 where the carrier lifetime increases from the second portion 202 toward the first portion 201. The lateral slope 213 is a portion where the carrier lifetime continuously increases from LT2 to LT1. In other words, the lateral slope 213 does not have a portion where the carrier lifetime decreases in a direction from the second portion 202 toward the first portion 201.

A width of the lateral slope 213 in the X axis direction is represented by W3. In this example, the width of the lateral slope 213 is calculated as the width of the lateral slope 212. The width W3 may be a width of a portion where the carrier lifetime increases from α×LT2 to β×LT1. α and β are similar to those of the examples shown in FIGS. 4 and 5. A value that is 2 times a width W4 of a portion where the carrier lifetime increases from LT2 to the average value of LT1 and LT2 may be set as the width of the lateral slope 213 in the X axis direction.

The lifetime adjustment region 206 of each example described in the present specification can be formed by irradiating, at the depth position Zp, charged particles of helium or the like from the upper surface 21 or lower surface 23 of the semiconductor substrate 10. When the charged particles are helium ions, a dose amount of helium ions may be 1×10¹⁰ ions/cm² or more and 1×10¹³ ions/cm² or less. The dose amount of helium ions may be 1×10¹¹ ions/cm² or more. The dose amount of helium ions may be 1×10¹² ions/cm² or less.

While the present invention has been described with the embodiments, the technical scope of the present invention is not limited to the above-described embodiments. It is apparent to persons skilled in the art that various alterations and improvements can be added to the above-described embodiments. It is also apparent from the scope of the claims that the embodiments added with such alterations or improvements can be included in the technical scope of the present invention.

Note that the operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the operation flow is described by using phrases such as “first” or “next” in the scope of the claims, specification, or drawings, it does not necessarily mean that the process must be performed in this order.

What is claimed is:

1. A semiconductor device including a semiconductor substrate having an upper surface and a lower surface, comprising:
a transistor portion provided in the semiconductor substrate;
a diode portion which is provided in the semiconductor substrate and is arranged next to the transistor portion in a first direction; and
a boundary region which is provided in the semiconductor substrate and is arranged between the transistor portion and the diode portion, wherein
the diode portion includes a lifetime adjustment region which is arranged in the upper surface side of the semiconductor substrate and contains a lifetime killer that adjusts a lifetime of carriers,
the boundary region includes:
a first portion which is in contact with the transistor portion and is not provided with the lifetime adjustment region; and
a second portion which is in contact with the diode portion and to which the lifetime adjustment region of the diode portion extends,
a density distribution of the lifetime killer in the first direction has a lateral slope where a density of the lifetime killer decreases from the second portion of the boundary region toward the first portion,
a width of the first portion is smaller than a width of the second portion in the first direction, and
the width of the first portion is equal to or larger than a width of the lateral slope in the first direction.

2. The semiconductor device according to claim 1, wherein
the density distribution of the lifetime killer in a depth direction of the semiconductor substrate has a density peak in the second portion, and
the width of the first portion in the first direction is equal to or larger than a peak width of the density peak in the depth direction.

3. The semiconductor device according to claim 2, wherein
the width of the first portion in the first direction is equal to or larger than a distance from the upper surface of the semiconductor substrate to the density peak.

4. The semiconductor device according to claim 1, wherein
the transistor portion includes:
a plurality of trench portions arranged next to one another in the first direction; and
a mesa portion sandwiched between two of the trench portions, and
the width of the first portion in the first direction is 2 times or more of a width of the mesa portion in the first direction.

5. The semiconductor device according to claim 1, wherein
the transistor portion includes:
a plurality of trench portions arranged next to one another in the first direction; and
a mesa portion sandwiched between two of the trench portions, and
the width of the first portion in the first direction is larger than a width obtained by adding a width of at least one of the trench portions and a width of two of the mesa portions sandwiching the trench portion in the boundary region.

6. The semiconductor device according to claim 1, wherein
the width of the first portion in the first direction is 1 μm or more.

7. The semiconductor device according to claim 6, wherein
the width of the first portion in the first direction is 10 μm or more.

8. The semiconductor device according to claim 1, wherein
a width of the boundary region in the first direction is 200 μm or less.

9. The semiconductor device according to claim 1, wherein
the width of the first portion in the first direction is 10% or more of a width of the boundary region in the first direction.

10. The semiconductor device according to claim 2, wherein
the width of the second portion in the first direction is equal to or larger than a distance from the upper surface of the semiconductor substrate to the density peak.

11. The semiconductor device according to claim 1, wherein
the semiconductor substrate includes a drift region of a first conductivity type,
the transistor portion includes:
an emitter region which is arranged between the drift region and the upper surface of the semiconductor substrate and has a higher doping concentration than the drift region;
a base region of a second conductivity type which is arranged between the emitter region and the drift region; and
an accumulation region which is arranged between the base region and the drift region and has a higher doping concentration than the drift region,
the accumulation region is arranged in at least a part of the first portion, and
the accumulation region is not arranged in the second portion.

12. The semiconductor device according to claim 1, wherein
the semiconductor substrate includes a drift region of a first conductivity type,
the transistor portion includes:
an emitter region which is arranged between the drift region and the upper surface of the semiconductor substrate and has a higher doping concentration than the drift region; and
a base region of a second conductivity type which is arranged between the emitter region and the drift region,
the diode portion includes:
an anode region of the second conductivity type which is arranged between the drift region and the upper surface of the semiconductor substrate, and
a doping concentration of the base region and a doping concentration of the anode region differ.

13. The semiconductor device according to claim 1, wherein
the semiconductor substrate includes a drift region of a first conductivity type,
the transistor portion includes:
a plurality of trench portions arranged next to one another in the first direction; and
a lower end region of a second conductivity type which is provided in contact with a lower end of at least a trench portion closest to the boundary region out of the plurality of trench portions, and
the lower end region is provided to extend to the second portion.

14. The semiconductor device according to claim 1, wherein
the semiconductor substrate includes a drift region of a first conductivity type,
the transistor portion includes:
a plurality of trench portions arranged next to one another in the first direction; and
a lower end region of a second conductivity type which is provided in contact with a lower end of at least a trench portion closest to the boundary region out of the plurality of trench portions, and
the lower end region is provided to extend to the first portion and is not provided in the second portion.

15. The semiconductor device according to claim 14, wherein
a distance between the lower end region and the second portion in the first direction is equal to or larger than the width of the lateral slope.

16. The semiconductor device according to claim 1, further comprising:
an upper surface electrode arranged above the upper surface of the semiconductor substrate; and
an interlayer dielectric film arranged between the upper surface electrode and the semiconductor substrate, wherein
in the boundary region, the interlayer dielectric film is provided with a contact hole that connects the upper surface electrode and the semiconductor substrate and has a longitudinal length in a second direction, and
when an end portion of the contact hole in the second direction is set as an end portion of the boundary region in the second direction, an area Sk of the second portion and an area S of the boundary region in a top view satisfy an expression below
0.8≤Sk/S<1.

17. A semiconductor device including a semiconductor substrate having an upper surface and a lower surface, comprising:
a transistor portion provided in the semiconductor substrate;
a diode portion which is provided in the semiconductor substrate and is arranged next to the transistor portion in a first direction;
a boundary region which is provided in the semiconductor substrate and is arranged between the transistor portion and the diode portion;
an upper surface electrode arranged above the upper surface of the semiconductor substrate; and
an interlayer dielectric film arranged between the upper surface electrode and the semiconductor substrate, wherein
the diode portion includes a lifetime adjustment region which is arranged in the upper surface side of the semiconductor substrate and contains a lifetime killer that adjusts a lifetime of carriers,
the boundary region includes:
a first portion which is in contact with the transistor portion and is not provided with the lifetime adjustment region; and
a second portion which is in contact with the diode portion and to which the lifetime adjustment region of the diode portion extends,
in the boundary region, the interlayer dielectric film is provided with a contact hole that connects the upper surface electrode and the semiconductor substrate and has a longitudinal length in a second direction, and
when an end portion of the contact hole in the second direction is set as an end portion of the boundary region in the second direction, an area Sk of the second portion and an area S of the boundary region in a top view satisfy an expression below
0.8≤Sk/S<1.

18. The semiconductor device according to claim 2, wherein
the semiconductor substrate includes a drift region of a first conductivity type,
the transistor portion includes:
an emitter region which is arranged between the drift region and the upper surface of the semiconductor substrate and has a higher doping concentration than the drift region;
a base region of a second conductivity type which is arranged between the emitter region and the drift region; and
an accumulation region which is arranged between the base region and the drift region and has a higher doping concentration than the drift region,
the accumulation region is arranged in at least a part of the first portion, and
the accumulation region is not arranged in the second portion.

19. The semiconductor device according to claim 3, wherein
the semiconductor substrate includes a drift region of a first conductivity type,
the transistor portion includes:
an emitter region which is arranged between the drift region and the upper surface of the semiconductor substrate and has a higher doping concentration than the drift region;
a base region of a second conductivity type which is arranged between the emitter region and the drift region; and
an accumulation region which is arranged between the base region and the drift region and has a higher doping concentration than the drift region,
the accumulation region is arranged in at least a part of the first portion, and
the accumulation region is not arranged in the second portion.

20. The semiconductor device according to claim 4, wherein
the semiconductor substrate includes a drift region of a first conductivity type,
the transistor portion includes:
an emitter region which is arranged between the drift region and the upper surface of the semiconductor substrate and has a higher doping concentration than the drift region;
a base region of a second conductivity type which is arranged between the emitter region and the drift region; and
an accumulation region which is arranged between the base region and the drift region and has a higher doping concentration than the drift region,
the accumulation region is arranged in at least a part of the first portion, and
the accumulation region is not arranged in the second portion.
